(19) United States
(12) Patent Application Publication
(10) Pub. No.: US 2011/0049454 A1
(43) Pub. Date: Mar. 3, 2011

(54) SEMICONDUCTOR DEVICE

(76) Inventors: Motoyasu Terao, Hinode (JP); Yuichi Matsui, Kawasaki (JP); Tsuyoshi Koga, Itami (JP); Nozomu Matsuzaki, Kodaira (JP); Norikatsu Takaura, Tokyo (JP); Yoshihisa Fujisaki, Hachioji (JP); Kenzo Kurotsuchi, Kodaira (JP); Takahiro Morikawa, Hachioji (JP); Yoshitaka Sasago, Tachikawa (JP); Junko Ushiyama, Kokubunji (JP); Akemi Hirotsune, Odawara (JP)

(21) Appl. No.: 12/305,890

(22) PCT Filed: Jun. 23, 2006
(86) PCT No.: PCT/JP2006/312640

§ 371 Date: Jul. 6, 2009

(51) Int. Cl. H01L 45/00

(52) U.S. Cl. 257/2; 257/E45.002

(57) ABSTRACT

In a phase-change memory, an interface layer is inserted between a chalcogenide material layer and a plug. The interface layer is arranged so as not to cover the entire interface of a plug-like electrode. When the plug is formed at an upper part than the chalcogenide layer, the degree of integration is increased. The interface layer is formed by carrying out sputtering using an oxide target, or, by forming a metal film by carrying out sputtering using a metal target followed by oxidizing the metal film in an oxidation atmosphere such as oxygen radical, oxygen plasma, etc.

### TECHNICAL FIELD

The present invention relates to semiconductor devices and a technique of manufacturing the same, and more particularly, it relates to a technique effectively applied to a semiconductor device having a phase-change memory formed by using a phase-change material such as chalcogenide.

### BACKGROUND ART

In mobile devices represented by mobile phones, semiconductor memories such as DRAM, SRAM, and FLASH memory are used. While DRAM has a large capacity, the access speed thereof is low. On the other hand, while the speed of SRAM is high, since many transistors as much as 4 to 6 transistors are required per one cell, it is difficult to increase the degree of integration, and it is not suitable for a large-capacity memory. Moreover, DRAM and SRAM always require power supply to retain data (volatile). On the other hand, while FLASH memory does not require power supply for electrical memory retention since it is non-volatile, it has disadvantages that the number of times of rewrite or erase is limited to about 10⁵ times and that the rewriting speed is slower than other memories by several digits. In this way, each of the memories has advantages and disadvantages, and currently, they are subjected to use depending on the characteristics thereof.

If a universal memory having advantages of the DRAM, SRAM, and FLASH memory in combination can be realized, a plurality of memories can be integrated in one chip, and downsizing and function enhancement of mobile phones or various mobile devices can be achieved. Furthermore, if all semiconductor memories can be replaced, the impact is significantly large. Factors required for the universal memory include, for example, increasing the degree of integration (increasing capacity) to the level of DRAM, high-speed access (write/read) to the level of SRAM, non-volatility like FLASH memory, and low-power consumption that can withstand small battery drive, etc.

Among next-generation non-volatile memories called universal memories, what is currently attracting attention the most is a phase-change memory. The phase-change memory uses a chalcogenide material that is used in optical disks such as CD-RW and DVD and similarly stores data by the difference between a crystalline state and an amorphous state. The difference between the phase-change memory and the optical disk resides in the writing/reading method. The optical disk utilizes transmission and reflection of light typified by laser; on the other hand, in the phase-change memory, write is performed by Joule heat generated by a current, and a signal is read by the difference of resistance values caused by phase change.

Here, operation principles of the phase-change memory (abbreviated name of a semiconductor memory device, the same goes to the following) will be described with FIG. 1 and FIG. 2. When the chalcogenide material is to be amorphized, a reset pulse that heats the temperature of the chalcogenide material to a melting point or above and then cools it rapidly is applied. The melting point is, for example, about 600° C. The time for rapid cooling (t1) is, for example, about 2 nsec. When the chalcogenide material is to be crystallized, a set pulse that keeps the temperature of the chalcogenide material to a temperature that is higher than or equal to a crystallization temperature and lower than or equal to the melting point is applied. The crystallization temperature is, for example, about 400° C. The time required for crystallization (t2) is, for example, about 50 nsec.

A feature of the phase-change memory lies in that a read signal is large since the resistance value of the chalcogenide material is changed by 2 to 3 digits in accordance with the crystalline state and the resistance value is used as the signal. As a result, sensing operation is facilitated, and the speed of reading is increased. In addition to this, it has a performance that compensates for the drawback of FLASH memory, for example, rewrite can be performed for 10¹² times. Moreover, such features as that operation can be performed with a low voltage and low power and that mixed embedding with a logic circuit is easy are suitable for mobile devices.

An example of a manufacturing process of a phase-change memory cell will be briefly described by using cross-sectional views of main parts of FIG. 3 to FIG. 5. First, starting from the explanation with FIG. 3, a select transistor is formed on a semiconductor substrate, which is not shown, by a known manufacturing method. The select transistor is formed by, for example, a MOS transistor or a bipolar transistor. Next, by using a known manufacturing method, an interlayer insulating film 1 comprising, for example, a silicon oxide film is deposited, and a plug 2 comprising, for example, tungsten is formed in the interlayer insulating film 1. The plug functions to electrically connect the select transistor in the lower part and a phase-change material layer in the upper part to each other. Then, a chalcogenide material layer 3 comprising, for example, GeSbTe; an upper electrode 4 comprising, for example, tungsten; and a hardmask 5 comprising, for example, a silicon oxide film are sequentially deposited, thereby making the state shown in FIG. 3.

Then, as shown in FIG. 4, the hardmask 5, the upper electrode 4, and the chalcogenide material layer 3 are sequentially processed by known lithography method and dry etching method. Then, an interlayer insulating film 6 is deposited, thereby making the state shown in FIG. 5. Then, a wiring layer electrically connecting to the upper electrode 4 is formed above the interlayer insulating film 6, and a plurality of wiring layers are further formed thereabove (not shown).

The phase-change memory cell is substantially completed by the above process. Note that, documents relating to this kind of phase-change memory cells include Non-Patent Document 1, and documents relating to phase change of chalcogenide materials include Non-Patent Document 2.
Patent Document 1: U.S. Pat. No. 5,536,947
Patent Document 2: Japanese Patent Application Laid-Open Publication No. 2003-174144
Patent Document 3: US Patent Application Publication No. US2004/0026731 Specification
Patent Document 4: US Patent Application Publication No. US2003/0047727 Specification
Non-Patent Document 1: Technical Digest of International Electron Device Meeting, 2001, p. 803-806
Non-Patent Document 2: Journal of Applied Physics, Vol. 87, No. 9, May, 2000, p. 4130

### DISCLOSURE OF THE INVENTION

### Problems to be Solved by the Invention

The present invention elucidates problems in a manufacturing process of a phase-change memory and problems in a rewrite operation, respectively, and provides means capable of solving the problems at the same time. Hereinafter, the problems to be solved will be explained sequentially.

The first problem is that a large current and large power consumption tend to be posed in a phase-change memory when it is changed from a low-resistance state to a high-resistance state since the temperature of the film is required to be increased to a high temperature that exceeds the melting point by Joule heat, which is caused by the current. With respect to this point, there is a known method in which a film of carbide, nitride, oxide, etc. is formed between a chalcogenide material layer and an electrode so as to narrow the current path in crystallization like a filament. For example, U.S. Pat. No. 5,536,947 Specification (Patent Document 1) describes that. However, when the layer of insulating substances including carbide, nitride, oxide, etc. is provided like Patent Document 1, a potential drop due to the layer occurs as a matter of course; thus, when it is changed from the high-resistance state to the low-resistance state, a threshold voltage at which transition to electronic low resistance begins is increased due to a carrier multiplication phenomenon such as impact ionization, and a problem that high-voltage power supply is needed is posed.

The second problem is that, since the chalcogenide material has a low adhesiveness, the film is prone to be delaminated from the substrate during the manufacturing process of the phase-change memory. Particularly, the chalcogenide material has a low adhesiveness with respect to the silicon oxide film; therefore, an adhesive layer is preferably provided between the chalcogenide material layer and an interlayer insulating film.

It has been already known that inserting an adhesive layer is effective to prevent delamination of a chalcogenide material layer in a phase-change memory. Publicly known examples include, for example, Japanese Patent Application Laid-Open Publication No. 2003-174144 (Patent Document 2), US Patent No. US2004/0026731 (Patent Document 3), US Patent US2003/0047727 (Patent Document 4), etc. In any of the publicly known examples, a conductor such as Ti is used specifically as an adhesive layer material.

FIG. 6 shows a cross-sectional structure of a memory cell of the case where an adhesive layer comprising a conductor is formed on a plug and an interlayer insulating film. Since a conductor adhesive layer 8 is provided on the entire interface between a chalcogenide material layer 3 and an interlayer insulating film 1, delamination of the chalcogenide material layer can be prevented. However, in this structure, when a voltage is applied from a plug 2 in a rewrite operation of the phase-change memory, a current flows mainly in a lateral direction (direction parallel to the substrate plane) of the adhesive layer 8 since resistivity of the conductor adhesive layer 8 is lower than that of the chalcogenide material layer 3. In this case, a region of the chalcogenide material layer to be heated by Joule heat is expanded to the entire surface of the part that is in contact with the adhesive layer 8; therefore, an extremely large current gets to be required for crystallizing or amorphizing the chalcogenide material layer.

The abovedescribed problem can be solved by forming the conductor adhesive layer 8 merely in a region that is not in contact with the plug 2 as shown in FIG. 7. In this case, the region of the chalcogenide material layer 3 that is heated by Joule heat is limited to the part that is in contact with the plug 2; therefore, the current required for crystallizing or amorphizing the chalcogenide material layer 3 is reduced compared with the case of FIG. 6. However, since a wide region in which no adhesive layer is provided on the interface of the chalcogenide material layer 3 is present, delamination of the chalcogenide material layer cannot be completely prevented.

Moreover, after the conductor adhesive layer 8 is formed on the entire surface of the substrate including the parts on the interlayer insulating film 1 and on the plug 2, a process of removing the conductor adhesive layer on the plug 2 is additionally required. In this case, there are posed problems that the number of masks is increased making manufacturing cost increased, and, when the memory cell is miniaturized, an alignment margin is reduced to reduce the yield and reliability. Therefore, means capable of reducing the current and preventing delamination of the chalcogenide material layer without adversely affecting rewriting characteristics of the phase-change memory have been desired.

The third problem is that, since rewrite is carried out by also utilizing heat generation of the plug in the structure formed in the order of a transistor, the plug electrode 1, the chalcogenide material layer 3, and an upper electrode 4 from the silicon substrate side in the abovedescribed manner, which is the most frequently used structure, when accesses for rewriting are concentrated to several memory elements in the vicinity of the structure, heat diffuses to the periphery of the transistors through the plugs having a high thermal conductivity and accumulates. Therefore, the distance between the plugs cannot be readily reduced, and the area cannot be reduced.

The fourth problem is that, for example, when a low-resistance material such as tungsten is used for the plug, an extremely large current is required for heating the chalcogenide material layer by Joule heat since heat readily escapes from the chalcogenide material layer via the plug. This is for the reason that materials having low resistivities generally have high thermal conductivities. Particularly, in a resetting (amorphization), heat diffusion from the plug is a large problem since the chalcogenide material layer is required to be heated to the melting point or above.

For example, in order to carry out mixed embedding with a logic circuit, the current required for rewriting has to be reduced to the level operable at least by a MOS transistor. In order to enable rewriting by a low current, the structure capable of suppressing the heat diffusion from the plug and efficiently heating the chalcogenide material layer is necessary to be used. Note that, in the case of an optical disk, since write/read is carried out by laser, the part electrically in contact with the chalcogenide material layer is not required. Therefore, the chalcogenide material layer will not be in contact with the material having a high thermal conductivity. In other words, the thermal diffusion via the material having high thermal conductivity is a problem what the phase-change memory which carries out write/read by electrical pulses uniquely has.

In order to suppress the heat diffusion from the plug, means of using a material having a high resistivity, i.e., a low thermal conductivity as the plug has been proposed. Publicly known examples applying a high-resistance material to the plug include, for example, Japanese Patent Application Laid Open Publication No. 2003-174144 (Patent Document 2). As specific high-resistance plug materials, TiSiN, TiAlN, and TiSiC are used. In this case, since new materials which have not been used in conventional logic circuits are required to be introduced, problems that manufacturing cost is increased and that yield and reliability are lowered are generated. Therefore, means capable of suppressing the heat diffusion even when the plug of a conventional low-resistance material is used have been desired. The chalcogenide material can be efficiently heated by that means; therefore, the current for rewriting of the phase-change memory can be lowered.

An object of the present invention is to provide a technique that realizes power reduction of a semiconductor device having a phase-change memory.

Another object of the present invention is to provide a technique that realizes an enhanced reliability of a semiconductor device having a phase-change memory.

The above and other objects and novel characteristics of the present invention will be apparent from the description of the present specification and the accompanying drawings.

### Means for Solving the Problems

The effects obtained by typical aspects of the present invention will be briefly described below.

There are comprised at least: a semiconductor substrate; a transistor formed on a main surface of the semiconductor substrate; an interlayer insulating film provided above the transistor; an electrode electrically connected to the transistor; a chalcogenide material layer provided to the electrode so as to be in contact with the electrode or via another layer; an interface layer provided on an upper part of the chalcogenide material layer and containing at least one element selected from a group comprising oxygen, nitrogen, carbon, and silicon; and a plug electrode provided above the interface layer, where the chalcogenide material layer exhibits a phase change by a tunneling current flowing through the interface layer.

More preferably, the interface layer is in contact with the interlayer insulating film and the plug to be formed as a continuous film.

More preferably, the interface layer is in contact with the plug to be formed as a continuous film, and also is formed so as to let the interlayer insulating film be in contact with part of the chalcogenide material layer.

More preferably, the interface layer is in contact with the interlayer insulating film to be formed as a continuous film, and is also formed so as to let the plug be in contact with part of the chalcogenide material layer.

More preferably, an average film thickness of the interface layer is 0.1 nm or more and 5 nm or less.

Further, there are comprised: a semiconductor substrate; a select transistor formed on a main surface of the semiconductor substrate; an interlayer insulating film provided above the select transistor; an interface layer formed on the interlayer insulating film; a chalcogenide material layer formed on the interface layer; and a plug formed between the interface layer and the select transistor in the interlayer insulating film, where the chalcogenide material layer exhibits a phase change by a tunneling current flowing through the interface layer, and the interface layer is formed so as to let part of the chalcogenide material layer be in contact with the plug.

More preferably, the interface layer is in contact with the interlayer insulating film to be formed as a continuous film.

More preferably, the interface layer is formed so as to let the interlayer insulating film be in contact with part of the chalcogenide material layer.

Further, there are comprised: a semiconductor substrate; a select transistor formed on a main surface of the semiconductor substrate; an interlayer insulating film provided above the select transistor; an interface layer formed on the interlayer insulating film; a chalcogenide material layer formed on the interface layer; and a plug formed between the interface layer and the select transistor in the interlayer insulating film, where the chalcogenide material layer exhibits a phase change by a tunneling current flowing through the interface layer, and the interface layer is formed so as to let part of the chalcogenide material layer be in contact with the interlayer insulating film.

More preferably, the interface layer is in contact with the plug to be formed as a continuous film.

More preferably, the interface layer is formed so as to let the plug be in contact with part of the chalcogenide material layer.

### Effects of the Invention

The effects obtained by typical aspects of the present invention will be briefly described below.

Power reduction of a semiconductor device having a phase-change memory can be realized. In addition, reliability of a semiconductor device having a phase-change memory can be improved.

### BRIEF DESCRIPTIONS OF THE DRAWINGS

FIG. 1 is a diagram showing current pulse specifications for changing the phase state of chalcogenide;

FIG. 2 is a diagram showing phase states of chalcogenide;

FIG. 3 is a cross-sectional view of main parts showing a manufacturing process of a phase-change memory cell according to conventional techniques;

FIG. 4 is a cross-sectional view of main parts showing the manufacturing process of the phase-change memory cell of the conventional techniques;

FIG. 5 is a cross-sectional view of main parts showing the manufacturing process of the phase-change memory cell according to the conventional techniques;

FIG. 6 is a cross-sectional view of a phase-change memory cell according to the conventional techniques;

FIG. 7 is a cross-sectional view of a phase-change memory cell according to the conventional techniques;

FIG. 8 is a diagram showing a calculation result of delamination energies according to the molecular dynamics;

FIG. 9 is a diagram showing a calculation result of delamination energies according to the molecular dynamics;

FIG. 10 is a diagram showing a calculation result of delamination energies according to the molecular dynamics;

FIG. 11 is a diagram showing a calculation result of delamination energies according to the molecular dynamics;

FIG. 12 is a cross-sectional view showing a phase-change memory cell according to the present invention;

FIG. 13 is a cross-sectional view showing a phase-change memory cell according to a first embodiment;

FIG. 14 is a cross-sectional view showing another example of the phase-change memory cell according to a first embodiment;

FIG. 15 is a cross-sectional view showing another example of the phase-change memory cell according to a first embodiment;

FIG. 16 is a diagram showing a relationship of a chalcogenide material layer and an interface layer;

FIG. 17 is a diagram showing a relationship of the chalcogenide material layer and the interface layer;

FIG. 18 is a diagram showing a relationship of the chalcogenide material layer and the interface layer;

FIG. 19 is a diagram showing a relationship of the chalcogenide material layer and the interface layer;

FIG. 20 is a diagram showing a relationship of the chalcogenide material layer and the interface layer;

FIG. 21 is a diagram showing a relationship of the chalcogenide material layer and the interface layer;

FIG. 22 is a diagram showing a relationship of the chalcogenide material layer and the interface layer;

FIG. 23 is a diagram showing a relationship of the chalcogenide material layer and the interface layer;

FIG. 24 is a diagram showing a relationship of the chalcogenide material layer and the interface layer;

FIG. 25 is a diagram showing a relationship of the chalcogenide material layer and the interface layer;

FIG. 26 is a diagram showing a relationship of the chalcogenide material layer and the interface layer; and

FIG. 27 is a diagram showing a phase-change memory cell according to a second embodiment.

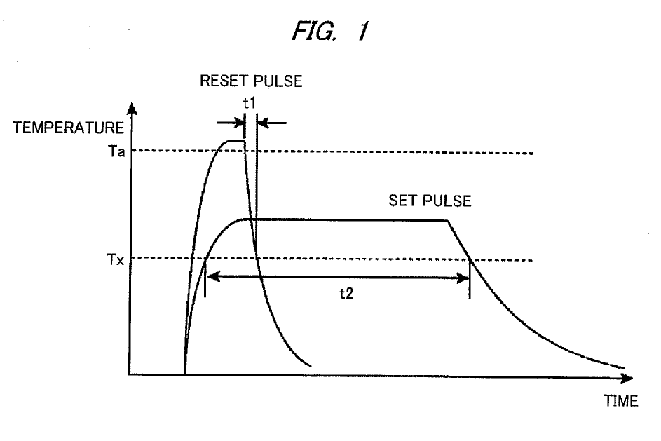

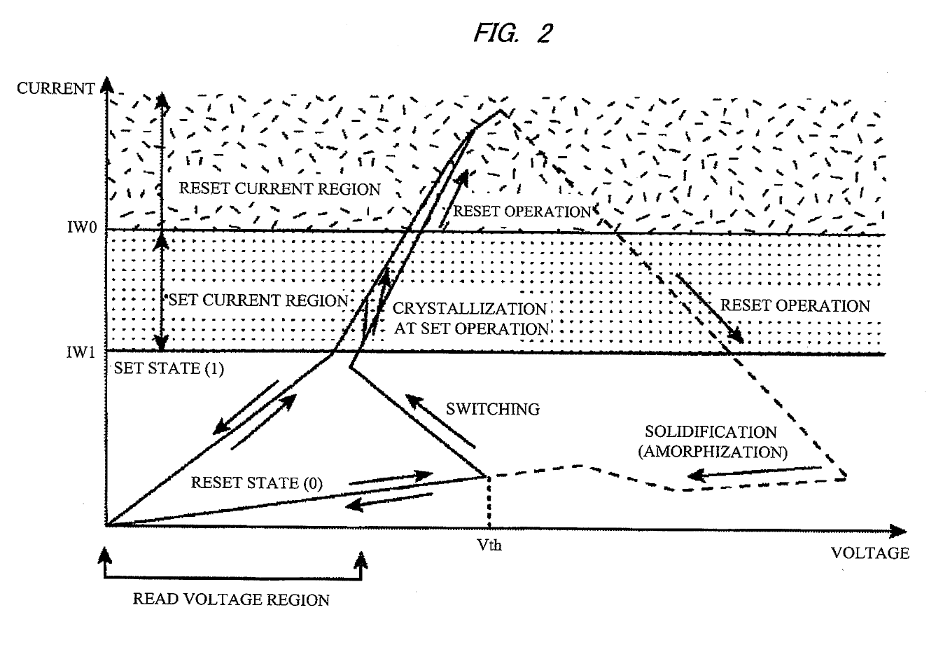

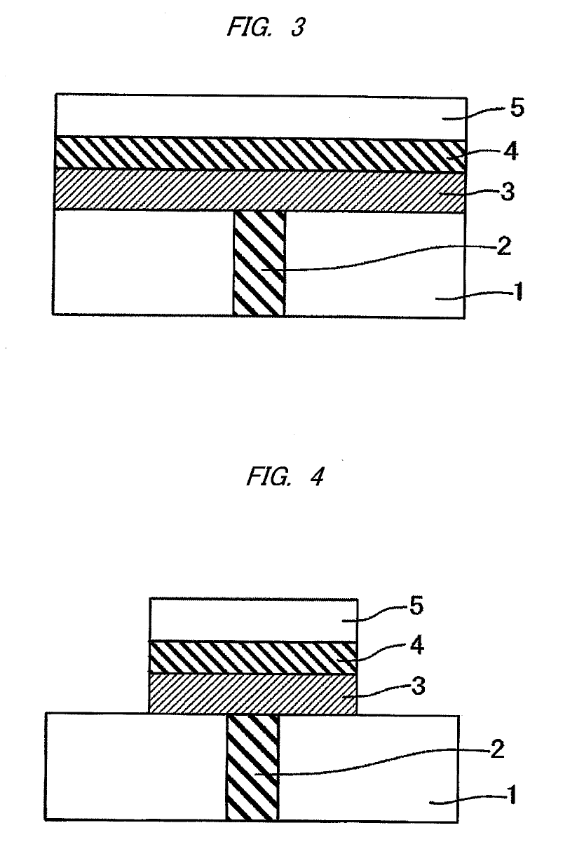

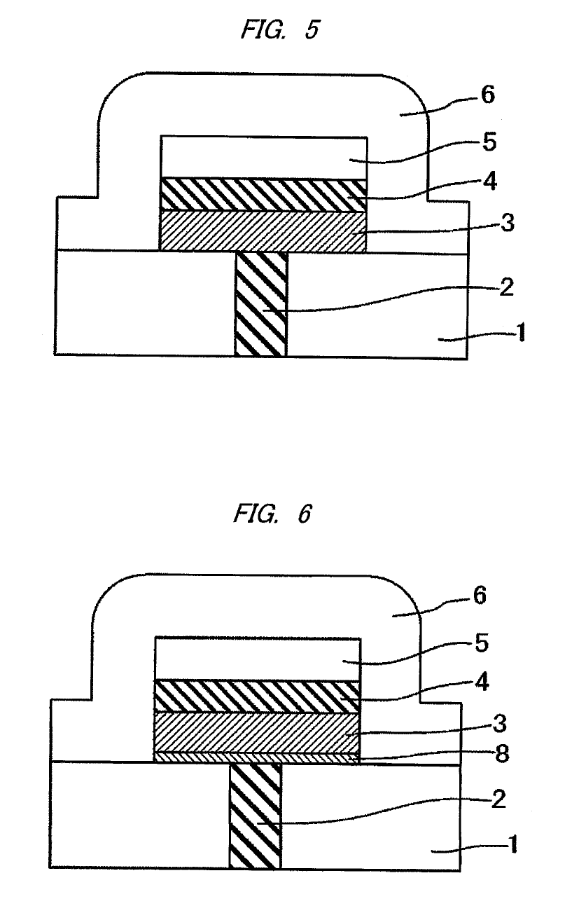

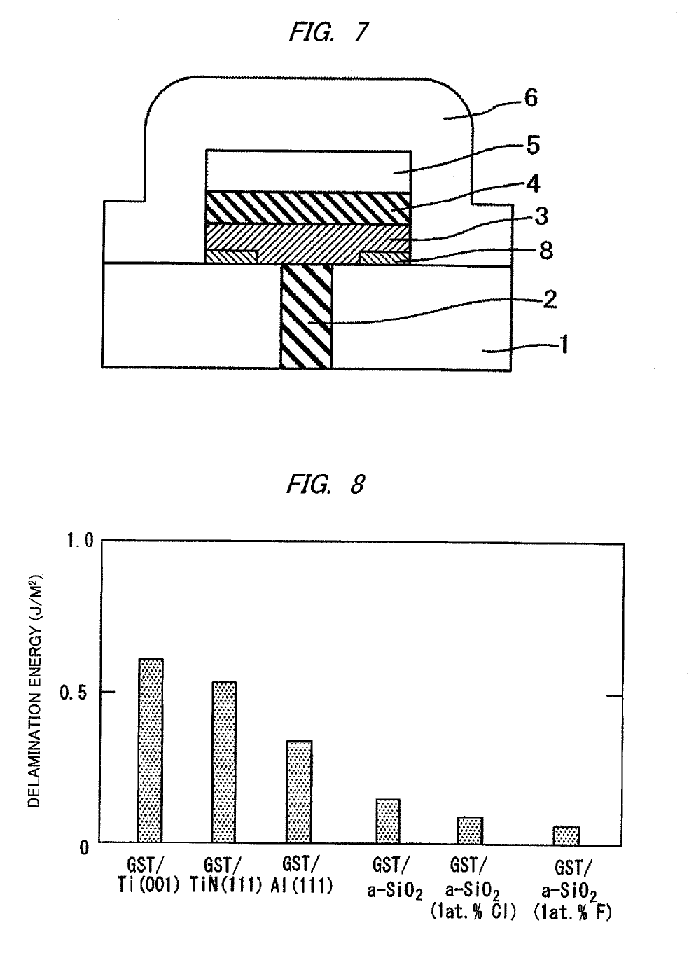

### BEST MODE FOR CARRYING OUT THE INVENTION

Conventionally, conductive materials such as Ti and Al have been used as an interface layer for improving adhesiveness. This is for the reason that the bonding force of the interface is enhanced and delamination resistance is improved because, generally, the conductive materials readily react with chalcogenide materials. However, the inventors of the present invention have found that delamination of a chalcogenide material layer can be prevented not only by the conductive material but also by using insulating materials as an adhesive layer. This is for the reason that the bonding force is enhanced since even insulating materials somewhat react with chalcogenide materials and that insulating materials have high resistance to dry etching processes. Hereinafter, details thereof will be described.

Results of carrying out molecular dynamics calculations of the interface delamination strength are shown in FIG. 8 to FIG. 11. As a chalcogenide material, GeSbTe (hereinafter, described as GST) is presupposed, and energy required to delaminate a GST film at an interface of an underlaying material to be adhered was calculated. This is defined as delamination energy. When the underlaying material is a crystal, a crystal plane conducive to orient is presupposed. For example, since the (001) plane of Ti readily grows in a direction parallel to the substrate surface, the delamination energy of the interface of GST and Ti (001) is obtained.

In a manufacturing process of a phase-change memory, the probability of delamination is high when a chalcogenide material layer is processed by a dry etching method like a structure shown e.g. in FIG. 4. The dry etching method is often carried out in an atmosphere containing Cl and F; therefore, it is considered that Cl and F diffuse to the interface of GST and the underlaying material. Therefore, delamination energies of the cases in which Cl and F are assumed to diffuse to the interface of GST and the underlaying material by 1 atom percent (at. %) are also obtained by calculations.

First, the results of FIG. 8 will be described. It can be understood that, compared with the cases in which the underlaying material is Ti (001), TiN (111), or Al (111), the delamination energy is very small in the case of amorphous SiO2 (a-SiO₂). This result supports the fact that the interface of GST and a-SiO2 is readily delaminated. It can be understood that, when Cl and F are interposed in the interface of GST and a-SiO₂, the delamination energy is further lowered. Thus, it can be considered that, when GST is processed by the dry etching method like in FIG. 4, GST becomes readily delaminatable due to Cl and F diffusing to the interface of GST and the interlayer insulating film.

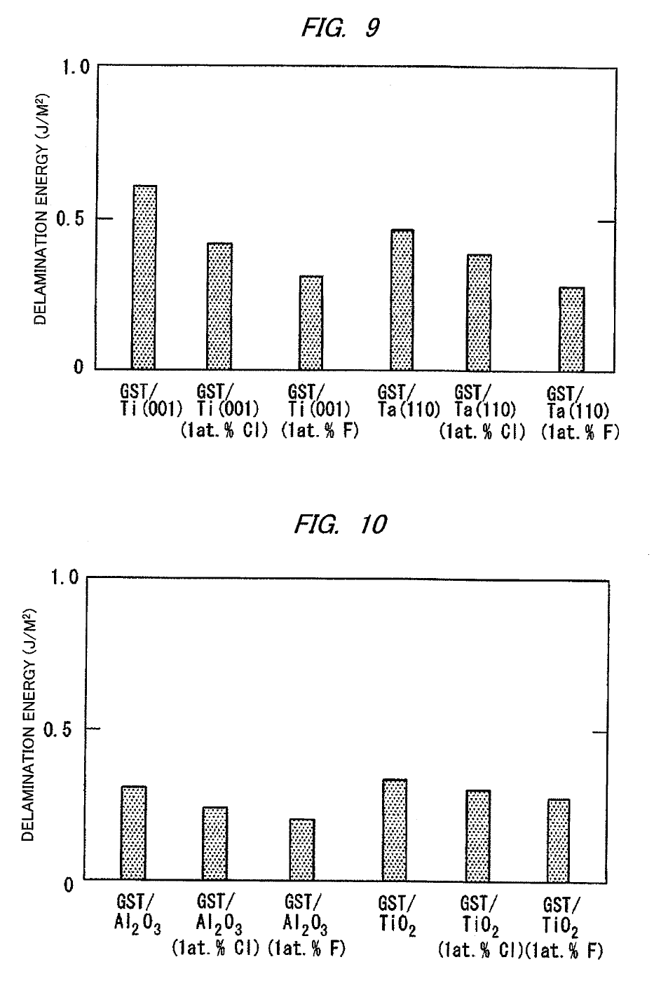

Next, the results of FIG. 9 will be described. The delamination energy is comparatively large in the interface of GST and Ti (001) and the interface of GST and Ta (110), and it can be considered that they cannot be readily delaminated. However, it can be understood that, when Cl and F are interposed in the interface, the delamination energies are significantly lowered. Meanwhile, even if Cl and F diffuse and the delamination energies are lowered, they are considered to function as the adhesive layers since the delamination energies are still large compared with the interface of a-SiO2 shown in FIG. 8. However, when a conductor such as Ti and Ta is used as the adhesive layer, a very large current is required for rewriting the chalcogenide material layer as described above.

Next, the results of FIG. 10 will be described. The delamination energy of an interface of GST and Al₂O₃ and the interface of GST and TiO2 is small compared with that of the conductors such as Ti and Ta shown in FIG. 9; however, it can be understood that the delamination energy is larger than that of the interface of GST/a-SiO₂ shown in FIG. 8. Moreover, as compared with GST/a-SiO₂ shown in FIG. 8, reduction in the delamination energy when Cl or F is interposed in the interface is small. This result indicates that the insulating materials such as Al₂O₃ and TiO₂ have high resistance to the dry etching processes, and the materials are considered to be desirable as the adhesive layer.

Next, the results of FIG. 11 will be described. The delamination energies of the interface of GST and Ta₂O₅ and the interface of GST and Cr₂O₃ are larger than that of Al₂O₃ and TiO₂ shown in FIG. 10. Further, the delamination energies of the cases in which Cl and F are interposed in the interfaces are larger than that of the conductors such as Ti and Ta shown in FIG. 9. This result indicates that Ta₂O₅ and Cr₂O₃ are extremely desirable as adhesive layers. Among the materials studied this time, Cr₂O₃ is the most desirable as the adhesive layer of the insulating material, Ta₂O₅ is next most desirable, and other desirable materials are TiO₂, Al₂O₃, etc.

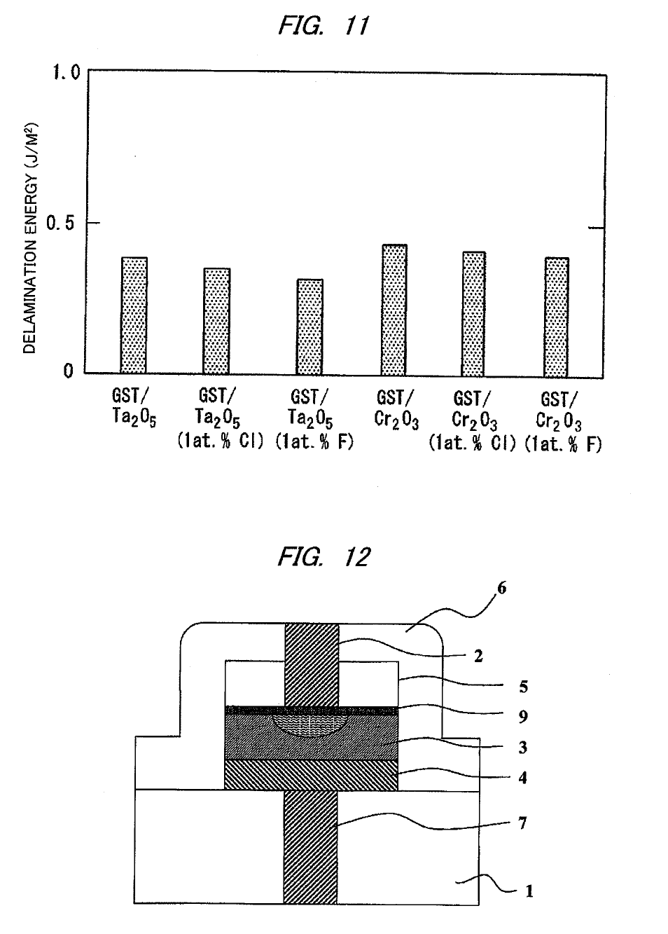

Next, fabrication processes will be explained by using FIG. 12. FIG. 12 is a schematic diagram for describing the outline of the invention of the present application. Note that, in the present description, for the sake of convenience, conductive layers for connecting respective wiring layers or a chalcogenide material layer will be called contacts, and, among them, the conductive layer that is in contact with a part of the chalcogenide material layer, which exhibits a phase change, via an interface layer is called a plug. Moreover, in FIG. 12, a semicircular region is a cross section of a semispherical region, which is a region that is prone to be in an amorphous state when heated to the melting point or above showing that a phase change mainly occurs in this region in the chalcogenide material layer.

First of all, a select transistor (not shown) and an interlayer insulating film 1 are formed, and a transistor and a memory operating part above are connected by a contact 7. Then, a lower electrode 4 comprising, for example, tungsten (W); the chalcogenide material layer 3 comprising, for example, GeSbTe; the interface layer 9 comprising, for example, tantalum oxide; and a hardmask 5 comprising a silicon oxide film are sequentially deposited. Then, the hardmask 5, the interface layer 9, the chalcogenide material layer 3, and the lower electrode 4 are processed by known lithography and dry etching method. Then, an interlayer insulating film 6 is deposited; a plug hole that reaches the interface layer is formed by the lithography and dry etching method; and tungsten is embedded therein, for example, by a CVD method followed by removing W on the upper surface of the interlayer insulating film 6, for example, by a CMP method; as a result, the state shown in FIG. 12 is achieved.

In formation of the plug hole that reaches the interface layer 9, dry etching is necessary to be carried out under the conditions that the interlayer insulating film 6 and the hardmask 5 are sufficiently highly selective with respect to the interface layer 9. The conditions that cause a small damage to the interface layer 9, which is exposed in the dry etching, are preferably used.

According to the present invention, the interface layer of an insulating substance is formed between the plug 2 and the chalcogenide material layer 3; consequently, heat diffused from the low-resistance plug can be suppressed. This is for the reason that insulating materials have lower thermal conductivity compared with conductive materials. For example, while the thermal conductivity of tungsten which is a conductor is 1.74 W/cm·K (27° C.), the thermal conductivity of a titanium oxide which is an insulator is 6.5×10⁻² W/cm·K (100° C.) which is smaller by about two digits. Therefore, when the interface layer comprising an insulator is inserted between the chalcogenide material layer and the plug, escape of the heat from the chalcogenide material layer via the plug can be suppressed. As a result, since the chalcogenide material can be efficiently heated, the current for rewriting the phase-change memory can be reduced. Since the plug is at the upper surface of the chalcogenide layer 3, an arrangement is possible where the plug can be laterally moved by utilizing the lower electrode having a wide area so that the plug is immediately above the transistor, and it can improve the degree of integration.

The average film thickness of the interface layer is, although it depends on the material of the interface layer, desirably 0.1 nm or more. More desirably, 0.5 nm or more.

The interface layer may be amorphous or polycrystal. For example, crystal grain boundaries are present in the film of the polycrystal. In the case of the insulating substance in which the Fermi level is not in an upper part of the band gap, but in the part close to the center thereof, the film thickness of the interface layer has to be thinner than a film thickness at which a tunneling current flows through the insulating film. This is for the reason that a necessary current has to be caused to flow from the plug to the chalcogenide material layer in order to heat the chalcogenide material layer to the melting point or above by Joule heat. Generally, a serial resistance of the insulating film is increased in an exponential manner with respect to the film thickness.

It is known that a current of about 100 μA to 1 mA is required in order to heat the chalcogenide material layer to the melting point or above. For example, in order to generate the current of 100 μA at a voltage of 3 V, the resistance of the interface layer has to be at least 30 kΩ or less. In order to realize the serial resistance of 30 kΩ or less by using the insulating film, the film thickness has to be reduced to a regime where the tunneling current is dominant. For this purpose, the film thickness has to be at least 5 nm or less, and, in order to obtain a sufficiently large current, the film thickness is desirably 3 nm or less.

When the film thickness is as thin as 3 nm, in considerable cases, pinholes are present, and the interlayer insulating layer and the chalcogenide layer, or the tungsten plug and the chalcogenide layer are partially in contact. Meanwhile, in the former case, there is no particular problem as long as the effect of the adhesiveness thereof is not lost. Further, between the tungsten plug and the chalcogenide layer, as described above, the resistance value of the interface layer has to be lowered in order to ensure the rewriting current. On the contrary, heat diffusion has to be also prevented. Therefore, when the interface layer is formed so that part of the chalcogenide material layer is in contact with the tungsten plug, the balance between the resistance value and thermal diffusion of the interface layer can be optimized.

An usable material for the interface layer comprising an insulator is a material having higher adhesiveness to the chalcogenide material layer than that of the interlayer insulating film material (for example, silicon oxide film) and having a smaller thermal conductivity than that of the plug material (for example, tungsten). Examples of the material include a Ti oxide film, a Zr oxide film, a Hf oxide film, a Ta oxide film, a Nb oxide film, a Cr oxide film, a Mo oxide film, a W oxide film, and an Al oxide film.

Even when a semiconductor material is used as the adhesive layer, delamination of the chalcogenide material layer can be prevented. When, for example, Si is used as the adhesive layer and, for example, GeSbTe is used as the chalcogenide material layer, the bonding force therebetween is extremely strong since Si and Ge readily make substitution reactions with each other.

As is clear from the description above, since the interface layer 9 comprising the insulating film having a thickness (about 0.1 to 5 nm) at the degree that allows the tunneling current to flow between the chalcogenide material layer 3 and the plug 2 is present, heat diffusion from the chalcogenide material layer 3 to the tungsten plug 2 having high thermal conductivity can be prevented, and the rewriting current can be reduced. Moreover, since the interface layer 9 is present between the chalcogenide material layer 3 and the insulating film 5, delamination during the manufacturing process can be prevented. Note that, when either one of the above-described configurations is provided, the corresponding effects are exerted; and, when both of the structures are provided, both of the problems can be solved. Even when both the configurations are provided, there is no additional manufacturing process since they can be formed by the same process. In addition, the device's characteristics and lifetime are also improved. Regarding this, the shape of the Schottky barrier of the interface is changed due to the interface layer, the potential gradient is increased, carriers are accelerated, and impact ionization tends to occur; therefore, switching to the low-resistance state in setting is carried out at a low voltage. It is considered that the increase of the potential gradient causes extremely-short-cycle variations of the composition in the chalcogenide material layer, which causes a resistance to crystallization, and lifetime at high temperature is improved.

The interface layer may be either amorphous or polycrystal. For example, crystal grain boundaries are present in the film of the polycrystal. However, since the polycrystal has lower resistance than the case of amorphous, when a voltage is applied from the plug in a rewriting operation of the phase-change memory, a current readily flows in the lateral direction (direction parallel to the substrate plane) of the adhesive layer. Consequently, the region of the chalcogenide material layer that is heated by Joule heat is expanded; therefore, a larger current is required for crystallizing or amorphizing the chalcogenide material layer. Thereby, the interface layer comprising the semiconductor is desired to be amorphous rather than being polycrystalline.

In another example, films of an interlayer insulating layer, a lower electrode, an interface layer (tantalum oxide), a chalcogenide layer, an interface layer (tantalum oxide), and an interlayer insulating layer are fabricated above a drive transistor; a hole for a plug is formed; and a tungsten plug is formed. Forming the interface layers on both sides of the chalcogenide layer in this manner is further preferred in terms of adhesiveness. Even when either one of the interface layers is omitted, the adhesiveness that is better than the case having no interface layer can be obtained; however, the device characteristics are better when the interface layer (lower side) that is not in contact with the plug is omitted. In the plug side, since the area of the lower electrode is wider, currents are concentrated to the outer-edge part of the plug, and, in this part, the Ti, TiN, or tungsten oxide of the plug's outer-edge part readily diffuses into the chalcogenide material. Therefore, for example, characteristics are readily changed when rewriting is repeated a number of times; however, the interface layer is expected to have the effect of preventing this.

Here, a desirable process for forming a continuous interface layer, which comprises an insulator, between the chalcogenide material layer 3 and the plug 2 which is a first means of the present invention will be described in detail.

For example, when a tantalum oxide film is formed as an interface layer material, generally, a method of carrying out sputtering in an oxidation atmosphere by using a tantalum metal target is used. This method is called a reactive sputtering method since a tantalum oxide is formed when the surface of the tantalum metal target is reacted with oxygen in the vapor phase and oxidized. According to a general reactive sputtering method, the in-plane distribution of the film thickness of the tantalum oxide is about 5% at 1σ. Since the serial resistance of the insulator is changed in the exponential manner with respect to the film thickness, the film-thickness variation of 5% causes resistance variation of one digit or more.

When the reactive sputtering method is used, oxidation of the chalcogenide layer which is formed before the interface layer is a problem. The chalcogenide layer 3 is deposited by using a known manufacturing method. Then, when the interface layer comprising, for example, a tantalum oxide film is deposited by using a reactive sputtering method of conventional techniques, a surface of the chalcogenide material layer 3, that is, the chalcogenide layer 3 is oxidized by oxygen plasma in the sputtering atmosphere. As a result, the composition of the chalcogenide material layer 3 is varied, thereby affecting variations of characteristics.

In other words, when an insulating film is formed by using a general reactive sputtering method to form the interface layer on the upper surface of the chalcogenide material layer, oxygen diffuses into the chalcogenide material layer, and variations of characteristics may be caused since the manner of the diffusion varies. Therefore, a new problem of the characteristic variations of the chalcogenide material layer may be posed.

Accordingly, more preferably, as a formation method of the insulator interface layer, means of forming a metal film by carrying out sputtering by using a metal target and then oxidizing the metal film in an oxidation atmosphere of, for example, oxygen radical, oxygen plasma, etc. is used. The chalcogenide material layer is formed by using a known sputtering method. Then, for example, a tantalum metal film is deposited by using a known sputtering method. Then, the tantalum metal film is oxidized by oxygen radical, thereby forming a tantalum oxide film. By using the means, the interface layer comprising the tantalum oxide film can be formed by optimizing the radical oxidation time without oxidizing the surface of the chalcogenide material layer. In other words, variations of the chalcogenide material layer can be prevented by preventing the composition shifts of the chalcogenide material layer.

In addition, in the sputtering method, the in-plane uniformity of the film thickness can be enhanced when the metal film is deposited compared with the case in which the oxide film is deposited. Therefore, compared with the case where the tantalum oxide film is formed by the reactive sputtering method, the uniformity of the film thickness is improved in the case where the tantalum metal film is subjected to post-oxidation so as to form the tantalum oxide film. In other words, variations of the film thickness of the tantalum oxide film causing resistance variations can be reduced.

However, the adhesiveness improving effect is exerted even when the film thickness is thin and pinholes are present, or, in an extreme case, the film is separated into island-like films in a part other than the part near the plug that contributes to electrical conduction. In the part away from the plug, thermal stress is small; therefore, even when the chalcogenide layer is in direct contact with the interlayer insulating layer since the interface layer is not formed or removed during processes, the problem of delamination does not readily occur compared with the case in which there is no interface layer formed.

As is clear from the above explanation, the in-plane uniformity of the oxide film thickness can be improved by using the means of forming the metal film by sputtering by using a metal target and then oxidizing the metal film in an oxidation atmosphere such as oxygen radical, oxygen plasma, etc. as a formation method of the insulator interface layer. Specifically, the in-plane distribution of the thickness of the tantalum oxide film is 1% or less at 1σ. As a result, the in-plane variations of resistance can be suppressed to one digit or less.

In order to further enhance the in-plane uniformity of the film thickness of the insulator interface layer, first of all, arrangements for uniformly forming the metal film have to be made. Desirable means therefor will be sequentially described. Note that all of the means are not necessarily required, and arbitrary selection can be made in consideration of required specifications and cost.

First one is a high ultimate vacuum of a sputtering chamber. An ultrahigh vacuum of 10 to 6 Pa or less is desirably obtained. A second one is a low discharge pressure. Discharge is desirably carried out at 0.1 Pa or less. A third one is a long distance between the target and the substrate. The distance is desirably 15 cm or more. A fourth one is to carry out film formation while rotating the substrate.

Next, arrangements for uniformly oxidizing the metal film have to be made. For this purpose, an oxidizing agent and an oxidizing temperature capable of obtaining a controllable oxidation rate are necessary to be selected. Generally, oxidation at a room temperature by using the oxygen radical is desirable. As a matter of course, depending on the material of the metal film, using oxygen or oxygen plasma as the oxidizing agent may be more desirable in some cases, and carrying out oxidation treatment while heating may be more desirable in some cases. Meanwhile, successively carrying out the process of oxidizing the metal film without exposing it to the atmospheric air by transporting the substrate in vacuum after the process of forming the metal film is desirable.

Hereinafter, embodiments of the present invention will be described in detail with reference to the accompanying drawings. Note that, components having the same function are denoted by the same reference symbols throughout the drawings for describing the embodiment, and the repetitive description thereof will be omitted. In addition, in the explanation below, typical means for solving the above-described two problems at the same time will be described below, and more specific examples will be described after that.

### First Embodiment

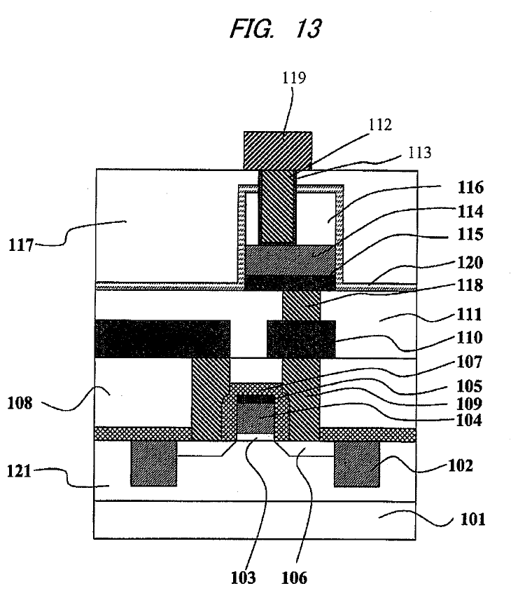

A first embodiment of the present invention will be described with FIG. 13. This embodiment is to form an interface layer comprising an insulator on an upper surface of a chalcogenide material layer and a part between an interlayer insulating film and a lower surface of a plug formed above the chalcogenide material layer, and this is an example specifically showing first means of forming a phase-change memory cell in a semiconductor memory device of the above-described invention.

First of all, a semiconductor substrate 101 is prepared, and a MOS transistor to be used as a select transistor is made. For that, first, an isolation oxide film 102 for isolating the MOS transistor are formed in a surface of the semiconductor substrate 101 by using a known selective oxidation method or shallow-trench isolation method. In the present embodiment, a shallow-trench isolation method capable of planarizing the surface is used.

First, isolation trenches are formed in the substrate by using a known dry etching method and the damage on the sidewalls and bottom surfaces of the trenches caused by the dry etching are removed, then an oxide film is deposited by using a known CVD method, and the oxide film in the parts that are not the trenches are selectively polished by a known CMP method so that merely the isolation oxide films 102 embedded in the trenches are caused to remain. Next, a well 121 is formed by high-energy impurity implantation.

Next, after cleaning the surface of the semiconductor substrate, a gate oxide film 103 of the MOS transistor is grown by a known thermal oxidation method. On a surface of the gate oxide film 103, a gate electrode 104 comprising polycrystalline silicon and a silicon nitride film 105 are deposited. Subsequently, after processing the gate by a lithography process and a dry etching process, an impurity is implanted while using the gate electrode and a resist as a mask, thereby forming a diffusion layer 106. In the present embodiment, a polycrystalline polysilicon gate is used as the gate electrode 104; however, as a low-resistance gate, a polymetal gate having a stacked structure of metal/barrier metal/polycrystalline silicon can be also used.

Then, for applying a self-aligned contact, the silicon nitride film 107 is deposited by a CVD method. Then, an interlayer insulating film 108 comprising a silicon oxide film is deposited on the entire surface and subjected to planarization of the surface irregularities, which are caused by the gate electrode 104, by using a known CMP method (Chemical Mechanical Polishing method).

Subsequently, contact holes are formed by a lithography process and a dry etching process. In these processes, in order to avoid exposure of the gate electrode, the interlayer insulating film 108 is processed under conditions of so-called self alignment, in other words, under conditions that the silicon oxide film is highly selective with respect to the silicon nitride film.

Note that, as countermeasures against misalignment of the contact holes with respect to the diffusion layer 106, first of all, the interlayer insulating film 108 is subjected to dry etching under the conditions that the silicon oxide film is highly selective with respect to the silicon nitride film, thereby causing the silicon nitride film on the upper surface of the diffusion layer 106 to remain; and, subsequently, dry etching is carried out under conditions that the silicon nitride film is highly selective with respect to the silicon oxide film, thereby removing the silicon nitride film on the upper surface of the diffusion layer 106.

Subsequently, tungsten is embedded in the contact holes, and first tungsten contacts 109 are formed by a known CMP method. Then, tungsten having a film thickness of 100 nm is deposited by a sputtering method, and the tungsten is processed by a lithography process and a dry etching process, thereby forming a first wiring layer 110. Subsequently, a second tungsten contact 118 is formed.

Then, a lower electrode 115 comprising tungsten and having a film thickness of 50 nm and a chalcogenide material layer 114 comprising GeSbTe and having a film thickness of 100 nm are sequentially deposited by a known sputtering method. Subsequently, a silicon oxide film 116 is deposited by the known CVD method. Subsequently, the silicon oxide film 116, the chalcogenide material layer 114 and the lower electrode 115 are sequentially processed by known lithography process and dry etching process.

Then, a sidewall protective film 120 comprising a silicon nitride film having a film thickness of 20 nm is deposited by a publicly known CVD method. Note that the sidewall protective film has to be formed under conditions of a low temperature and a high pressure so that the chalcogenide material does not sublimate. For example, a pressure of 0.1 Pa or more and a temperature of 45° C. or less can be exemplified as the conditions.

Then, an interlayer insulating film 117 comprising a silicon oxide film is deposited on the entire surface and subjected to planarization of the surface irregularities thereof by using a publicly known CMP method. Subsequently, a plug hole is formed by a lithography process and a dry etching process. Subsequently, an interface layer 113 is formed by a sputtering method, and tungsten is embedded therein so that a tungsten plug 112 is formed by a publicly known CMP method. Note that, when the interface layer is formed by a sputtering method, the layer is not formed at all or an extremely thin layer is formed on the side surface of the plug hole. However, there is no problem since the interface layer is formed above the chalcogenide material layer at the bottom surface. Subsequently, aluminium having a film thickness of 200 nm is deposited and processed as a wiring layer, thereby forming a second wiring layer 119. As a matter of course, instead of aluminium, copper having a low resistance can be also used. According to the foregoing, the structure of FIG. 13 can be realized.

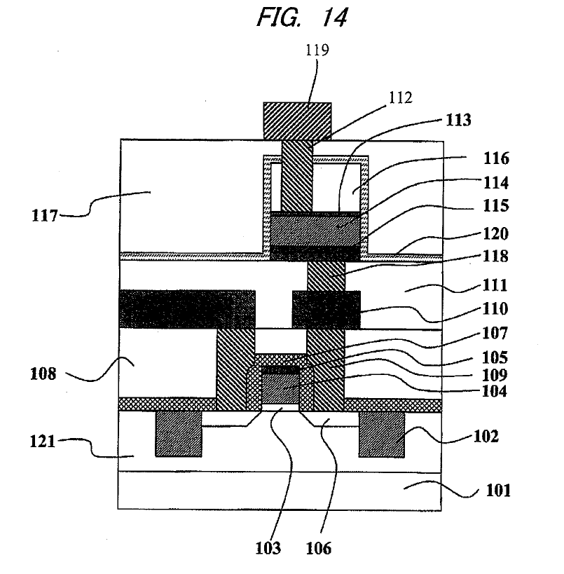

Next, another manufacturing method and another structure will be described using FIG. 14. A point different from FIG. 13 is that the interface layer 113 is formed on the entire upper surface of the chalcogenide material layer 114 in FIG. 14 while, in FIG. 13, the interface layer 113 is formed along the hole in which the tungsten plug 112 is formed.

Next, the manufacturing method of the present structure will be described using FIG. 14. Since the process is same as FIG. 13 until the point where the second tungsten contact 118 is formed, the descriptions thereof are omitted.

After formation of the second tungsten contact 118, the lower electrode 115 comprising tungsten and having a film thickness of 50 nm, the chalcogenide material layer 114 comprising GeSbTe and having a film thickness of 100 nm, and the interface layer 113 comprising a tantalum oxide and having a film thickness of 2 nm are sequentially deposited by a known sputtering method. Subsequently, the silicon oxide film 116 is deposited by a known CVD method. Subsequently, the silicon oxide film 116, the interface layer 113, the chalcogenide material layer 114, and the lower electrode 115 are sequentially processed by a known lithography process and a dry etching process. Herein, the processes can be simplified by etching the silicon oxide film 116 and the interface layer 113 in the same process and, with using them as a hardmask, by processing the chalcogenide material layer 114 and the lower electrode 115.

Then, as well as FIG. 13, the sidewall protective film 120 and the interlayer insulating film 117 are deposited and subjected to planarization of surface irregularities thereof by using a publicly known CMP method, and a plug hole is formed by a lithography process and a dry etching process. In this process, in order to prevent the interface layer from being etched, in the formation of the plug hole, the dry etching has to be carried out under a condition that the silicon oxide film 116 and the interlayer insulating film 117 are sufficiently highly selective with respect to the interface layer 113. Subsequently, tungsten is embedded in the plug hole so that the tungsten plug 112 is formed by a known CMP method.

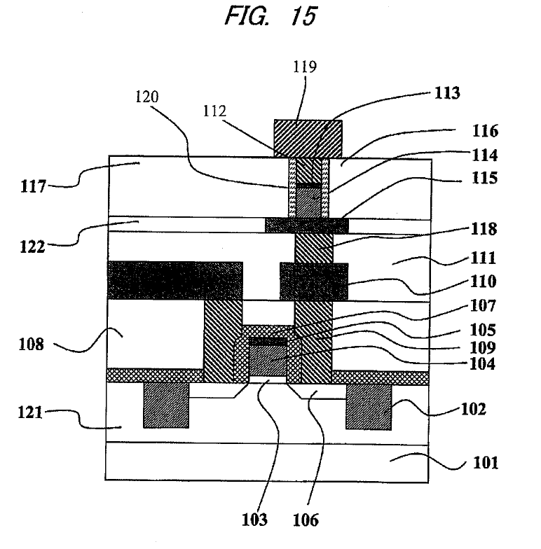

FIG. 15 is a diagram showing another structure and another manufacturing method. The point different from FIG. 13 and FIG. 14 is that the tungsten plug 112, the interface layer 113, and the chalcogenide material layer 114 in the upper part are formed to have the same width. In addition, the tungsten plug 112 is not in a cylindrical shape, but in a prismatic shape.

Hereinafter, the manufacturing method thereof will be described using FIG. 15. Since the process is same as FIG. 13 and FIG. 14 until the point where the second tungsten contact 118 is formed, the descriptions thereof are omitted.

After formation of the second tungsten contact 118, tungsten having a film thickness of 50 nm is deposited, and the lower electrode 115 is formed by a known lithography process and a dry etching process. Then, an insulating film 122 is deposited, and the lower electrode 115 is exposed by a CMP method. Next, the chalcogenide material layer 114 comprising GeSbTe and having a film thickness of 100 nm, the interface layer 113 comprising a tantalum oxide and having a film thickness of 2 nm, and the tungsten plug 112 are sequentially deposited by a known sputtering method. Subsequently, the tungsten plug 112, the interface layer 113, and the chalcogenide material layer 114 are sequentially processed by a known lithography process and a dry etching process. Furthermore, the sidewall protective layer 120 is formed so as to serve as a sidewall. The processes after this are same as FIG. 13 and FIG. 14. Note that, in FIG. 15, the lower electrode 115 is directly connected to the chalcogenide material layer 114; however, a conductive layer having the same width as the chalcogenide material layer 114 may be provided between the chalcogenide material layer 114 and the lower electrode 115. Alternatively, a configuration in which, without providing the lower electrode 115, the chalcogenide material layer 114 or a conductive layer having the same width as the chalcogenide material layer 114 is directly in contact with the second tungsten contact 118 may be also employed. However, when the lower electrode 115 having a width wider than that of the chalcogenide material layer (more desirably, a width wider than that of the second tungsten contact 118) is provided, alignment is facilitated.

The center part of the surface of the tungsten plug 112 that is in contact with the interface layer 113 may be formed by an insulating film so as to have a shape close to a rectangular tube or a cylinder. In this manner, the effect of reducing a current that flows from the tungsten plug 112 to the chalcogenide material layer can be obtained. The interface layer below the tungsten plug 112 may be formed to include the part of the insulating layer at the center same as the first embodiment; however, the interface layer may be formed merely in the interface between the layer and the tubular plug or in an area narrower than that.

According to the first embodiment, since the interface layer is formed between the chalcogenide material layer 114 and the tungsten plug 112, the heat diffusion from the plug of the low-resistance material is suppressed, and the chalcogenide material is efficiently heated; therefore, the current for rewriting the phase-change memory can be reduced. Furthermore, since the configuration of FIG. 14 has the interface layer between the insulating film 116 and the chalcogenide material layer 114, delamination of the chalcogenide material layer and the insulating layer 116 can be prevented.

On the other hand, in the configuration of FIG. 13, the interface layer is not present between the insulating film 116 and the chalcogenide material layer. However, manufacturing thereof is easier compared with the configuration of FIG. 14 since the interface layer which is extremely thin is not etched. Note that the insulating film 116 may use a material having a good adhesiveness to the chalcogenide material 114 instead of SiO₂. Furthermore, in FIG. 15, since the chalcogenide material layer 114 is not present above an insulating film 111, the adhesiveness of the insulating film 111 and the chalcogenide material layer 114 becomes unnecessary to be taken into consideration.

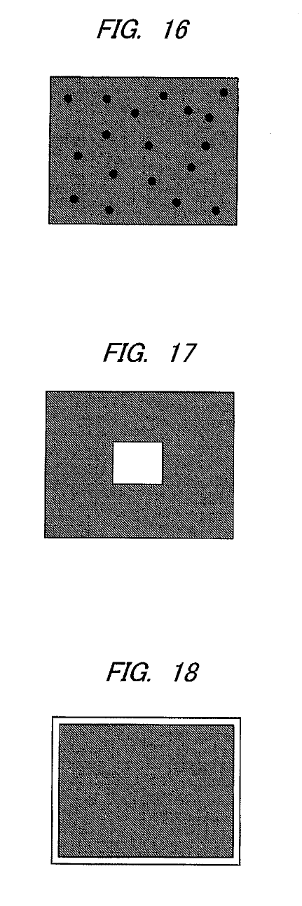

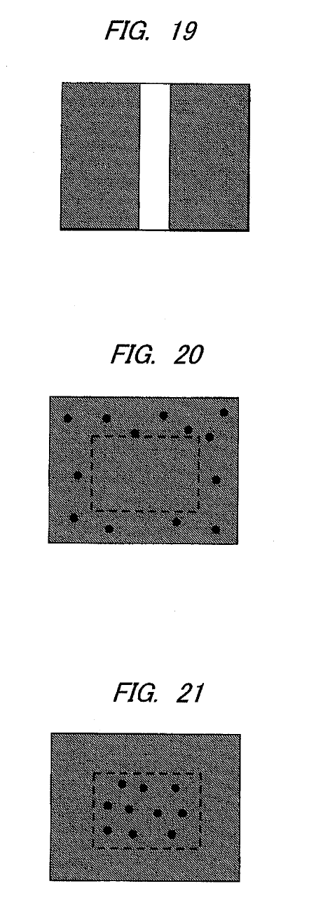

FIG. 16 to FIG. 26 show modification examples of the shape of the part of the interface layer that is in contact with the chalcogenide material layer. Note that FIG. 16 to FIG. 26 are schematic diagrams in which the outer squares represent the surface of the chalcogenide material layer, and the rounding of corners thereof is not taken into consideration. FIG. 16 is an example of forming pinholes in the interface layer. FIG. 17 shows the case where the interface layer 113 is like a ring, and FIG. 18 shows the case where the outer edge part is etched to reduce the area. FIG. 19 shows the case where the interface layer 113 is like slits.

Note that, when the ring-like or the slit-like interface layer 113 is to be formed, a mask is used. Furthermore, FIG. 20 and FIG. 21 show the case where no or comparatively few pinholes are provided in the region that is in contact with the plug electrode, and the case where pin holes are present merely in the region that is in contact with the plug electrode or comparatively many pinholes are in the region that is in contact with the plug electrode.

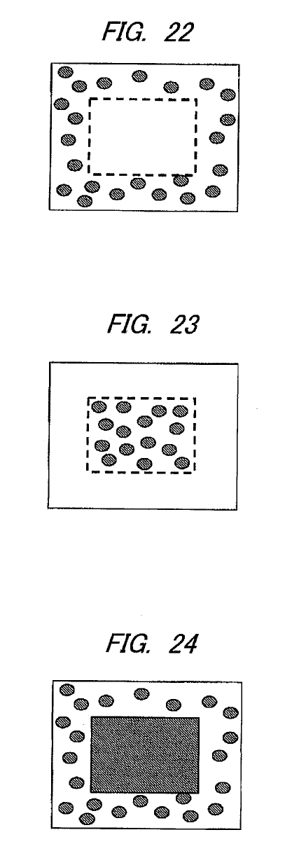

In the case of the interface layer material having effects relating to electrical characteristics such as reset current reduction, set voltage reduction, thermal resistance improvement, and improvement of the number of times of rewriting, the pinhole distribution of FIG. 20 is preferred than that of FIG. 21. On the other hand, when the resistance of the interface layer has to be lowered, FIG. 21 is more preferred. FIG. 22 and FIG. 23 show the cases where the interface layer separated like islands is present merely in the region of the plug electrode or merely outside the region.

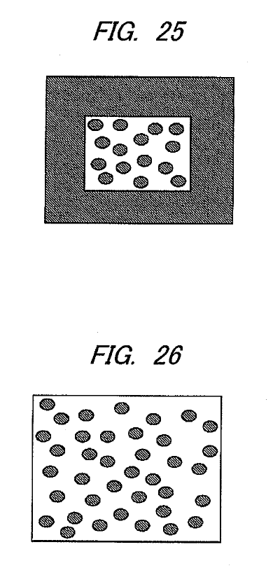

Further, FIG. 24 and FIG. 25 show the cases where the interface layer is a continuous film in the region where the layer is not like island-like. Pinholes may be present in the region of the continuous film. The boundaries in FIG. 20 to FIG. 25 are not necessarily completely matched with the shape or size of the plug electrode. FIG. 26 shows the case where the interface layer is like islands corresponding to the entire chalcogenide layer. The cases of FIG. 16 to FIG. 26 except for FIG. 18 may be combined with FIG. 18, in other words, the interface layer corresponding to the outermost peripheral part of the chalcogenide layer may not be present. FIG. 20 to FIG. 25 correspond to the case of FIG. 14 where the interface layer is larger than the size of the plug electrode. Note that, in any of the cases, the interface layer 113 has a film thickness that allows the tunneling current to flow. If the film thickness does not allow the tunneling current to flow, as explained by the first problem, the voltage to be applied to the memory cell may be increased.

Thus, although the interface layer 113 has been described as a continuous film in FIG. 13 to FIG. 15, the interface layer is not necessarily a continuous film. When the interface layer 113 between the tungsten plug 112 and the chalcogenide material layer 114 is a continuous film, the heat diffusion to the tungsten plug 112 can be reduced; however, a voltage drop may occur due to the resistance of the interface layer 113. In other words, the prevention of the heat diffusion to the tungsten plug 112 and increase of the resistance value of the interface layer 113 per se are in the relation of tradeoff. Therefore, instead of causing the interface layer 113 that is in contact with the tungsten plug 112 to be a continuous film, when the part that is in direct contact with the tungsten plug 112 and the chalcogenide material layer 114 is partially formed like FIG. 16 to FIG. 19, FIG. 21, FIG. 23, and FIG. 25, optimal structures can be formed with respect to the prevention of heat diffusion and increase of the resistance value.

Hereinabove, the tantalum oxide film has been used as the insulator interface layer 113 in the first embodiment; however, the interface layer is not limited thereto, and an insulating film such as a titanium oxide film, a zirconium oxide film, a hafnium oxide film, a niobium oxide film, a chromium oxide film, a molybdenum oxide film, a tungsten oxide film, an aluminium oxide film etc. can be used.

As the formation method of the insulator interface layer, an oxide film may be formed by carrying out sputtering by using an oxide target, or an oxide film may be formed by carrying out sputtering by using a metal target in an oxidation atmosphere. Alternatively, an oxide film may be formed by forming a metal film by carrying out sputtering by using a metal target and then oxidizing the metal film in an oxidation atmosphere such as oxygen radical, oxygen plasma, etc.

The composition of the oxide film may be an oxygen-excessive composition or an oxygen-deficient composition instead of the so-called stoichiometrical composition. For example, to describe the case of the tantalum oxide film, although the stoichiometrical composition thereof is Ta₂O₅, similar effects can be obtained even when the composition ratio of oxygen with respect to tantalum is smaller than or larger than 5/2. When the composition ratio of oxygen is smaller than 5/2, in other words, when it has an oxygen-deficient composition, the reactivity with the chalcogenide material layer is enhanced than the case where the tantalum oxide film of the stoichiometric composition is used; therefore, this case is more desirable as the adhesive layer.

In the above-described examples, GeSbTe has been used as the chalcogenide material layer; however, the chalcogenide material layer is not limited thereto, and a chalcogenide material containing at least two elements or more selected from Ge, Sb, and Te may be used. Also, a chalcogenide material containing at least two elements or more selected from Ge, Sb, and Te and at least one element selected from the elements of the Group 3b, the Group 2b, the Group 1b, the Groups 3a to 7a, and the Group 8 of the periodic table may be used.

When both the interface layer and the plug are positioned above the chalcogenide layer like the present embodiment, first of all, reduction of the area can be realized. However, the surface of tungsten of the lower electrode is prone to be irregular, and the irregularities affect the upper part, thereby often reducing the number of rewritable times and reducing the lifetime in high-temperature, for example; however, since the interface layer moderates local electric field concentration, improvement can be achieved.

Note that, according to the present invention, it goes without saying that, not only the above-described embodiment, but also various means described above can be applied. For example, the interface layer 113 may be formed of semiconductor. The interface layer comprising semiconductor may either be amorphous or polycrystal. However, since the polycrystal has a lower resistance than the case of amorphous, when a voltage is applied from the plug in a rewriting operation of the phase-change memory, a current readily flows in the lateral direction of the adhesive layer (direction parallel to the substrate plane). Consequently, the region of the chalcogenide material layer that is heated by Joule heat is expanded; therefore, a larger current is required for crystallizing or amorphizing the chalcogenide material layer. Therefore, the interface layer comprising semiconductor is more desirably amorphous than polycrystal.

Further, an impurity is not desired to be added to the interface layer comprising semiconductor. For example, it is known that the electrical conductivity is increased when an impurity such as P (phosphorous), As (arsenic), Sb (antimony), B (boron), etc. is added into silicon. In this case, the resistance of the interface layer is reduced, and a larger current is required to rewrite the chalcogenide material layer. However, since the reduction of the resistance is small when the impurity is not activated, the influence of impurity addition is small when an amorphous semiconductor interface layer is used.

Moreover, the film thickness of the interface layer comprising semiconductor is necessary to be a film thickness that causes the resistance in the vertical direction (direction perpendicular to the substrate plane) to be sufficiently lower than the resistance in the lateral direction (direction parallel to the substrate plane). If the resistance in the lateral direction (direction parallel to the substrate plane) is low, when a voltage is applied from the plug in a rewriting operation of the phase-change memory, a current mainly flows in the lateral direction through the interface layer. In this case, the region of the chalcogenide material layer that is heated by Joule heat is expanded to the entire surface of the part that is in contact with the interface layer; therefore, an extremely large current is required for rewriting the chalcogenide material layer. When the resistance in the vertical direction (direction perpendicular to the substrate plane) is reduced by reducing the film thickness of the semiconductor interface layer as much as possible, the current readily flows in the vertical direction from the plug via the semiconductor interface layer; therefore, the current does not spread in the lateral direction. As a result, the region of the chalcogenide material layer that is heated by Joule heat is limited to the vicinity of the plug; therefore, the current required for rewriting the chalcogenide material layer can be reduced. The film thickness of the semiconductor interface layer is necessary to be at least 5 nm or less; and, in order to obtain a sufficiently large current, the film thickness is desirably 3 nm or less.

The material of the interface layer comprising semiconductor is only required to be a material having a higher adhesiveness to the chalcogenide material layer than that of the interlayer insulating film material (for example, a silicon oxide film) and having a smaller thermal conductivity than that of the plug material (for example, tungsten). For example, examples of the material include Si, Ge, SiC, etc. Among these, Si is the most desirable material since it has a high reactivity with GeSbTe and high compatibility with conventional techniques.

When the interface layer of the semiconductor material is used, the interface layer material and the plug material are sometimes reacted with each other during the manufacturing process of the phase-change memory. More specifically, when the temperature upon deposition of the insulating film 117 is increased, the tungsten plug 112 and the amorphous silicon interface layer 113 are reacted with each other, so that a silicide interface layer comprising tungsten silicide is formed.

According to the means, the adhesive layer comprising the semiconductor is formed on the entire lower surface of the chalcogenide material layer; therefore, the delamination strength can be enhanced so that delamination during the manufacturing process can be prevented. In addition, since the interface layer comprising silicide is formed on the plug, diffusion of heat from the low-resistance plug can be prevented. As a result, the chalcogenide material can be efficiently heated; therefore, the current for rewriting the phase-change memory can be reduced.

As is clear from the above descriptions, when a semiconductor material is used as the interface layer, even when the semiconductor material is reacted with the plug material during the manufacturing process, either one or both of the problem that the film is readily delaminated from the substrate during the manufacturing process of the phase-change memory and the problem that heat readily escapes from the chalcogenide material layer via the plug can be solved.

Herein, a desirable process for forming the interface layer 113 which is an insulator will be described in detail. The thickness of the above-described insulator has to be reduced to the level that allows a tunneling current to flow. In addition, the film thickness is required to be uniform since the device characteristics are largely changed if the film thickness is varied as a current flows via the insulator.

For example, when a tantalum oxide film is to be formed as the interface layer material, generally a method of carrying out sputtering by using a tantalum metal target in an oxidation atmosphere is used. This method is called a reactive sputtering method since tantalum oxide is formed when the surface of the tantalum metal target is reacted with oxygen in the vapor phase to be oxidized. According to a general reactive sputtering method, the in-plane distribution of the film thickness of the tantalum oxide is about 5% at 1σ. The serial resistance of the insulator is changed in the exponential manner with respect to the film thickness; therefore, a 5% film thickness variation causes resistance variations of one digit or more. In addition, when the reactive sputtering method is used, oxidation of the exposed part may become problematic. When the exposed part is oxidized, variation of the resistance value or the composition variation of the chalcogenide material layer is feared to occur.

Accordingly, the present invention uses, as a formation method of the insulator interface layer, a means of forming a metal film by carrying out sputtering using a metal target and then oxidizing the metal film in an oxidation atmosphere such as oxygen radical, oxygen plasma, etc. In other words, the tantalum metal film is deposited by using a known sputtering method. Then, the tantalum metal film is oxidized by the oxygen radical, thereby forming the tantalum oxide film. When the means is used, the interface layer comprising the tantalum oxide film can be formed without oxidizing the surface of the chalcogenide material layer by optimizing the radical oxidation time.

Moreover, in the sputtering method, the in-plane uniformity of the film thickness can be higher more in the case where the metal film is deposited than the case where the oxide film is deposited. Therefore, the uniformity of the film thickness is improved more in the case where the tantalum metal film is subjected to a post-oxidation to form the tantalum oxide film than the case where the tantalum oxide film is formed by the reactive sputtering method.

As is clear from the above descriptions, the in-plane uniformity of the oxide film thickness can be improved when the means of forming the metal film by carrying out sputtering using a metal target and then oxidizing the metal film in an oxidation atmosphere such as oxygen radical, oxygen plasma, etc. is used as the formation method of the insulator interface layer. Specifically, the in-plane distribution of the thickness of the tantalum oxide film becomes 1% or less at 1σ. As a result, the in-plane variation of the resistance can be suppressed to at least one digit or less.

In order to further heighten the in-plane uniformity of the film thickness of the insulator interface layer, first of all, arrangements for uniformly forming the metal film are necessary to be made. Desirable means therefor will be sequentially described. Note that all of the means are not necessarily required, and arbitrary selection can be made in consideration of required specifications and cost. First one is a high ultimate vacuum of a sputtering chamber. An ultrahigh vacuum of 10 to 6 Pa or less is desirably obtained. A second one is a low discharge pressure. Discharge is desirably carried out at 0.1 Pa or less. A third one is a long distance between the target and the substrate. The distance is desirably 15 cm or more. A fourth one is to carry out film formation while rotating the substrate.

Next, arrangements for uniformly oxidizing the metal film have to be made. For this purpose, an oxidizing agent and an oxidizing temperature capable of obtaining a controllable oxidation rate have to be selected. Generally, oxidation at a room temperature by using oxygen radical is desirable. As a matter of course, depending on the material of the metal film, using oxygen or oxygen plasma as the oxidizing agent may be more desirable in some cases, and carrying out oxidation treatment while heating may be more desirable in some cases. Meanwhile, successively carrying out the process of oxidizing the metal film without exposing it to the atmospheric air by transporting the substrate in vacuum after the process of forming the metal film is desirable.

When these means are employed in accordance with needs, specifically, the in-plane distribution of the thickness of the tantalum oxide film can be suppressed to 0.5% or less at 1σ.

### Second Embodiment

Hereinafter, an embodiment in which the plug electrode is placed at a lower position will be described. Although the example in which the entire plug electrode surface is covered by the interface layer will be described, as well as the above-described embodiment in which the plug electrode is positioned upper, the area of the interface layer is preferably limited like FIG. 16 to FIG. 26.

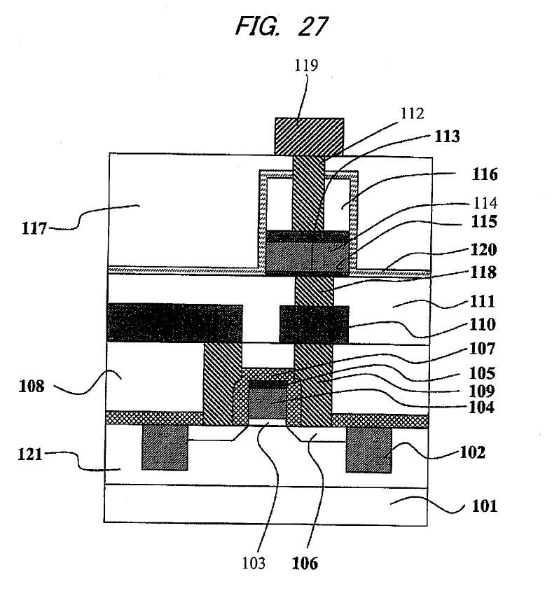

FIG. 27 is a diagram showing the embodiment in which the tungsten plug 112 is at a lower position. A difference from FIG. 14 is that, as the lower position of the tungsten plug 112, the interface layer 113 is disposed below the chalcogenide material layer 114.

Next, a manufacturing method thereof will be described. Note that, the processes until formation of the tungsten plug 112 are omitted since these are same as that of FIG. 14. Note that, it goes without saying that the tungsten contact 118 in FIG. 14 will serve as the tungsten plug 112.

Next, the insulator interface layer 113 comprising a tantalum oxide film and having a film thickness of 2 nm, the chalcogenide material layer 114 comprising GeSbTe and having a film thickness of 100 nm, and an upper electrode 115 comprising tungsten and having a film thickness of 50 nm are sequentially deposited by the sputtering method. Subsequently, the silicon oxide film 116 is deposited by the known CVD method. Subsequently, the silicon oxide film 116, the upper electrode 115, the chalcogenide material layer 114, and the insulator interface layer 113 are sequentially processed by the known lithography process and dry etching process.

Then, the interlayer insulating film 117 comprising a silicon oxide film is deposited on the entire surface, and the surface irregularities thereof are planarized by using the known CMP method. Hereinafter, the structure of FIG. 27 is completed when it is formed in the same manner as FIG. 14. Herein, the interface layer 113 may be a continuous film or may have the structures as shown in FIG. 16 to FIG. 25. The effects obtained here are also similar in this case. Meanwhile, although an embodiment of the case where the interface layer 113 is below the chalcogenide material layer 114 is not shown with respect to FIG. 15, it goes without saying that it can be formed in the manner similar to that of FIG. 27.

In this manner, when the tungsten plug is arranged below the chalcogenide material layer 114, the interface layer 113, which is extremely thin, will be arranged below the chalcogenide material layer 114. Consequently, the interface layer 113 can be processed in the same process as the chalcogenide material layer 114, which is comparatively thick, and the processes thereafter can be further carried out without exposing the upper surface of the interface layer 113. Therefore, processing after the interface layer formation is facilitated.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, while the select transistor has been described as the MOS transistor, the select transistor may comprise a diode transistor or a bipolar transistor. When it is formed by a diode transistor, the area can be further reduced.

### INDUSTRIAL APPLICABILITY

The present invention is applicable to a semiconductor device having a phase-change memory.

1. A semiconductor device comprising at least:
a semiconductor substrate;
a transistor formed on a main surface of the semiconductor substrate;
an interlayer insulating film provided above the transistor;
an electrode electrically connected to the transistor;
a chalcogenide material layer provided to the electrode so as to be in contact with the electrode or via another layer;
an interface layer provided in contact with an upper part of the chalcogenide material layer and containing at least one element selected from a group comprising oxygen, nitrogen, carbon, and silicon; and
a plug electrode provided in contact with an upper part of the interface layer.

2. The semiconductor device according to claim 1, wherein the interface layer is in contact with the interlayer insulating film and the plug to be formed as a continuous film.

3. The semiconductor device according to claim 1, wherein the interface layer is in contact with the plug to be formed as a continuous film, and also is formed so as to let the interlayer insulating film be in contact with part of the chalcogenide material layer.

4. The semiconductor device according to claim 1, wherein the interface layer is in contact with the interlayer insulating film to be formed as a continuous film, and is also formed so as to let the plug be in contact with part of the chalcogenide material layer.

5. The semiconductor device according to claim 1, wherein an average film thickness of the interface layer is 0.1 nm or more and 5 nm or less.

6. A semiconductor device comprising:
a semiconductor substrate;
a select transistor formed on a main surface of the semiconductor substrate;
an interlayer insulating film provided above the select transistor;
an interface layer formed on the interlayer insulating film;
a chalcogenide material layer formed on the interface layer; and
a plug formed between the interface layer and the select transistor in the interlayer insulating film so as to be in contact with the interface layer, wherein
the interface layer is formed so as to let part of the chalcogenide material layer be in contact with the plug, and
the interface layer is in contact with the interlayer insulating film to be formed as a continuous film.

7-8. (canceled)

9. A semiconductor device comprising:
a semiconductor substrate;
a select transistor formed on a main surface of the semiconductor substrate;
an interlayer insulating film provided above the select transistor;
an interface layer formed on the interlayer insulating film;
a chalcogenide material layer formed on the interface layer; and
a plug formed between the interface layer and the select transistor in the interlayer insulating film so as to be in contact with the interface layer, wherein
the interface layer is formed so as to let part of the chalcogenide material layer be in contact with the interlayer insulating film, and
the interface layer is in contact with the plug to be formed as a continuous film.

10-11. (canceled)

12. The semiconductor device according to claim 1, wherein the interface layer contains Ta₂O₅ or Cr₂O₃.

13. The semiconductor device according to claim 6, wherein the interface layer contains Ta₂O₅ or Cr₂O₃.

14. The semiconductor device according to claim 9, wherein the interface layer contains Ta₂O₅ or Cr₂O₃.
